(19) United States
(12) Patent Application Publication
(10) Pub. No.: US 2012/0068757 A1
(43) Pub. Date: Mar. 22, 2012

(54) SEMICONDUCTOR SWITCH

(75) Inventors: Toshiki Seshita, Kanagawa-ken (JP); Mitsuru Sugawara, Kanagawa-ken (JP)

(73) Assignee: KABUSHIKI KAISHA TOSHIBA, Tokyo (JP)

(21) Appl. No.: 13/046,934

(22) Filed: Mar. 14, 2011

(30) Foreign Application Priority Data
Sep. 22, 2010 (JP) 2010-212647

(51) Int. Cl. H03K 17/687; H03K 17/56

(52) U.S. Cl. 327/427; 327/419

(57) ABSTRACT

According to one embodiment, a semiconductor switch includes a power supply circuit, a control circuit and a switch circuit. The power supply circuit includes an internal potential generator connected to a power supply, and a first transistor connected between an input and an output of the internal potential generator. The internal potential generator generates a first potential higher than an input potential. The first transistor is turned on when the first potential becomes lower than the input potential and has a threshold voltage being set so as to keep the first potential not lower than the input potential. The control circuit is configured to receive the first potential to output a high-level or low-level control signal. The switch circuit is configured to receive an input of the control signal to switch connection between terminals.

### CROSS-REFERENCE TO RELATED APPLICATIONS

This application is based upon and claims the benefit of priority from the prior Japanese Patent Application No. 2010-212647, filed on Sep. 22, 2010; the entire contents of which are incorporated herein by reference.

### FIELD

Embodiments described herein relate generally to a semiconductor switch.

### BACKGROUND

In a radio frequency circuit of a cellular phone, a transmitting circuit and a receiving circuit are selectively connected to a common antenna via a radio frequency switch circuit. An insertion loss is one of important characteristic indexes in the radio frequency switch circuit.

In order to improve the insertion loss, it is required to increase a gate width of an FET constituting the radio frequency switch circuit and increase an ON voltage supplied to each gate. However, in terms of size reduction, there is a limitation in a current supply capability of an internal potential generator in the case where the ON voltage is internally generated. For this reason, in a switching operation, the ON voltage decreases and the insertion loss immediately after switching becomes large.

### BRIEF DESCRIPTION OF THE DRAWINGS

FIG. 1 is a block diagram illustrating a semiconductor switch according to a first embodiment;

FIG. 2 is a circuit diagram illustrating the configuration of the switch circuit of the semiconductor switch in FIG. 1;

FIG. 3 is a characteristic diagram showing ON potential dependency of the insertion loss;

FIG. 4 is a circuit diagram illustrating the configuration of a control circuit of the semiconductor switch shown in FIG. 1;

FIG. 5 is a circuit diagram illustrating the configuration of the level shifter of the driver;

FIG. 6 is a circuit diagram illustrating the configuration of a power supply circuit of the semiconductor switch shown in FIG. 1;

FIG. 7 is a sectional view of a first transistor;

FIG. 8 is a waveform diagram of the first potential on terminal switching;

FIG. 9 is a waveform diagram of the control signal on terminal switching;

FIG. 10 is a circuit diagram showing an equivalent circuit of the semiconductor switch on switching of connection in the switch circuit;

FIG. 11 is a circuit diagram showing an equivalent circuit for computing variation of the first potential;

FIG. 12 is a circuit diagram illustrating the configuration of a power supply circuit of a semiconductor switch according to a second embodiment; and

FIG. 13 is a circuit diagram illustrating the configuration of a step-down circuit of the power supply circuit shown in FIG. 12.

### DETAILED DESCRIPTION

In general, according to one embodiment, a semiconductor switch includes a power supply circuit, a control circuit and a switch circuit. The power supply circuit includes an internal potential generator connected to a power supply, and a first transistor connected between an input and an output of the internal potential generator. The internal potential generator generates a first potential higher than an input potential. The first transistor is turned on when the first potential becomes lower than the input potential and has a threshold voltage being set so as to keep the first potential not lower than the input potential. The control circuit is configured to receive the first potential to output a high-level or low-level control signal. The switch circuit is configured to receive an input of the control signal to switch connection between terminals.

Various embodiments will be described hereinafter in detail with reference to the accompanying drawings. The figures are schematic or conceptual, and shape, length and width of each component and ratio of components in size are not necessarily the same as those of original. Even the same component may be represented in different size and ratio according to the figures. The same components in the specification and the figures are given the same reference numerals, and detail description thereof is omitted.

### First Embodiment

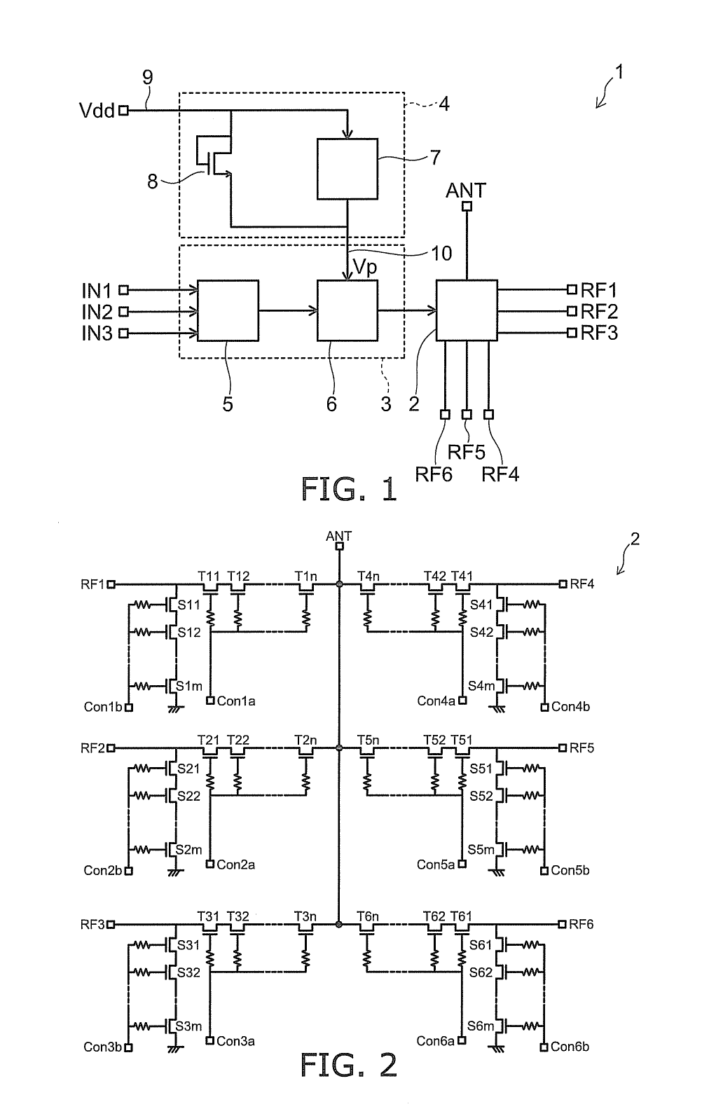

FIG. 1 is a block diagram illustrating the configuration of a semiconductor switch according to a first embodiment.

As shown in FIG. 1, the semiconductor switch 1 is provided with a switch circuit 2 for switching connection between a common terminal ANT and radio frequency terminals RF1 to RF6. The switch circuit 2 switches connection between the terminals according to a control signal outputted from a control circuit 3.

In the control circuit 3, a terminal switch signal inputted to switch signal terminals IN1 to IN3 is decoded in a decode circuit 5 and level-shifted in a driver 6 to be outputted as the control signal. A first potential Vp that is higher than a positive power potential Vdd is supplied to the driver 6 in the control circuit 3.

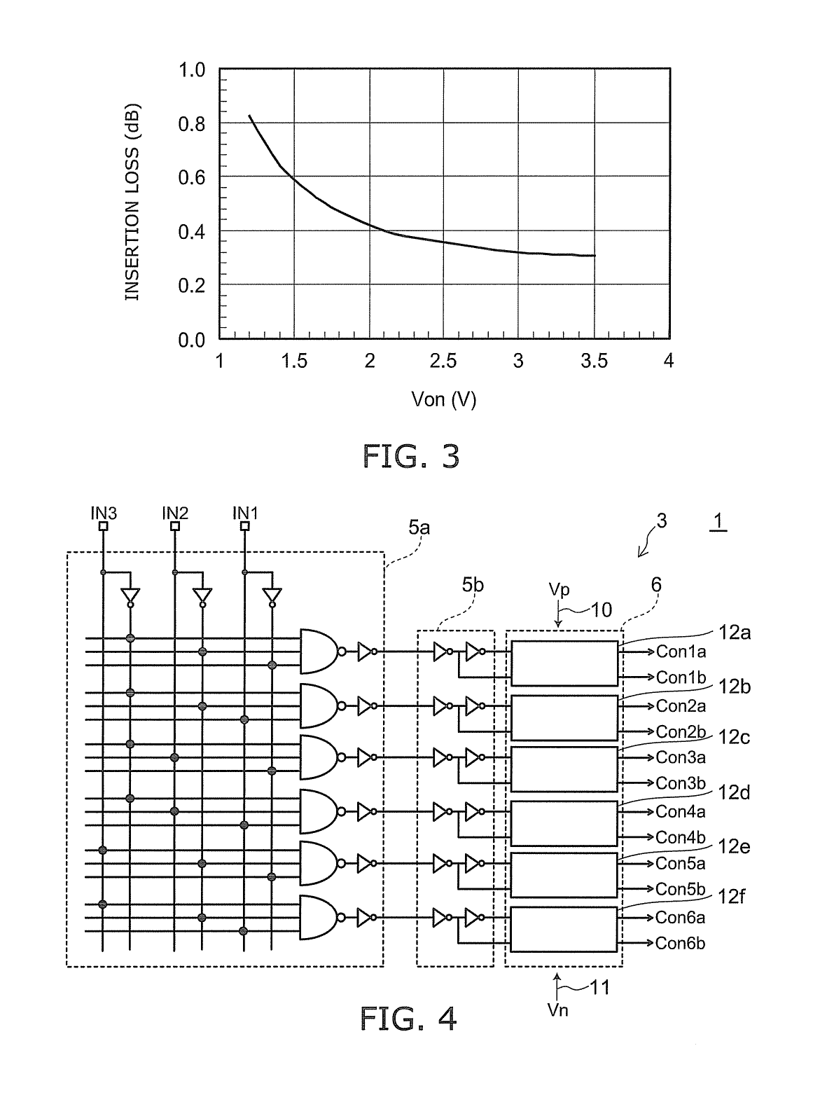

Here, the first potential Vp is a high-level potential of the control signal, which is applied to the gate of each FET in the switch circuit 2 to turn on each FET. As described with reference to FIG. 3, a steady value of the first potential Vp is set so that the insertion loss between the terminals is reduced to a desired value.

The first potential Vp is supplied from a power supply circuit 4. In the power supply circuit 4, an internal potential generator 7 receives an input of the positive power potential Vdd and generates the first potential Vp that is higher than an input potential Vdd. A first transistor 8 is connected between a power supply (power line) 9 as an input of the internal potential generator 7 and a high-potential power line 10 as an output of the internal potential generator 7.

A threshold voltage is set in the first transistor 8 so that the first transistor 8 is turned on when the first potential Vp becomes lower than the input potential Vdd. Thus, the first potential Vp outputted from the power supply circuit 4 is held to be equal to or higher than the input potential Vdd.

The semiconductor switch 1 is an SP6T (Single-Pole 6-Throw) switch for switching between the common terminal ANT and the radio frequency terminals RF1 to RF6.

Next, each circuit will be described.

FIG. 2 is a circuit diagram illustrating the configuration of the switch circuit of the semiconductor switch in FIG. 1.

As shown in FIG. 2, n-staged (n is a natural number) through FETs (Field Effect Transistor) T11 to T1n, T21 to T2n, T31 to T3n, T41 to T4n, T51 to T5n, T61 to T6n are connected in series between the common terminal ANT and the radio frequency terminals RF1 to RF6, respectively.

The through FETs T11 to Tin are connected between the common terminal ANT and the radio frequency terminal RF1. The through FETs T21 to T2n are connected between the common terminal ANT and the radio frequency terminal RF2. The through FETs T31 to T3n are connected between the common terminal ANT and the radio frequency terminal RF3. The through FETs T41 to T4n are connected between the common terminal ANT and the radio frequency terminal RF4. The through FETs T51 to T5n are connected between the common terminal ANT and the radio frequency terminal RF5. The through FETs T61 to T6n are connected between the common terminal ANT and the radio frequency terminal RF6.

m-staged (m is a natural number) shunt FETs S11 to Sim, S21 to S2m, 531 to S3m, S41 to S4m, S51 to S5m, S61 to S6m are connected in series between the radio frequency terminals RF1 to RF6 and the ground, respectively.

The shunt FETs S11 to S1m are connected between the radio frequency terminal RF1 and the ground. The shunt FETs S21 to S2m are connected between the radio frequency terminal RF2 and the ground. The shunt FETs S31 to S3m are connected between the radio frequency terminal RF3 and the ground. The shunt FETs S41 to S4m are connected between the radio frequency terminal RF4 and the ground. The shunt FETs S51 to S5m are connected between the radio frequency terminal RF5 and the ground. The shunt FETs S61 to S6m are connected between the radio frequency terminal RF6 and the ground.

Gates of the through FETs T11 to Tin connected to the radio frequency terminal RF1 are connected to a control terminal Con1a via respective radio frequency leakage inhibiting resistors. Gates of the shunt FETs S11 to S1m connected to the radio frequency terminal RF1 are connected to a control terminal Con1b via respective radio frequency leakage inhibiting resistors.

Gates of the through FETs T21 to T2n connected to the radio frequency terminal RF2 are connected to a control terminal Con2a via respective radio frequency leakage inhibiting resistors. Gates of the shunt FETs S21 to S2m connected to the radio frequency terminal RF2 are connected to a control terminal Con2b via respective radio frequency leakage inhibiting resistors.

Gates of the through FETs T31 to T3n connected to the radio frequency terminal RF3 are connected to a control terminal Con3a via respective radio frequency leakage inhibiting resistors. Gates of the shunt FETs S31 to S3m connected to the radio frequency terminal RF3 are connected to a control terminal Con3b via respective radio frequency leakage inhibiting resistors.

Gates of the through FETs T41 to T4n connected to the radio frequency terminal RF4 are connected to a control terminal Con4a via respective radio frequency leakage inhibiting resistors. Gates of the shunt FETs S41 to S4m connected to the radio frequency terminal RF4 are connected to a control terminal Con4b via respective radio frequency leakage inhibiting resistors.

Gates of the through FETs T51 to T5n connected to the radio frequency terminal RF5 are connected to a control terminal Con5a via respective radio frequency leakage inhibiting resistors. Gates of the shunt FETs S51 to S5m connected to the radio frequency terminal RF5 are connected to a control terminal Con5b via respective radio frequency leakage inhibiting resistors.

Gates of the through FETs T61 to T6n connected to the radio frequency terminal RF6 are connected to a control terminal Con6a via respective radio frequency leakage inhibiting resistors. Gates of the shunt FETs S61 to S6m connected to the radio frequency terminal RF6 are connected to a control terminal Con6b via respective radio frequency leakage inhibiting resistors.

Each of the control terminals Con1a to Con6a, Con1b to Con6b is connected to the control circuit 3.

FIG. 2 shows the SP6T switch as an example of the switch circuit 2. However, switches with other configuration can be similarly employed and for example, a kPIT (k is a natural number, I is an integer of 2 or more) switch can be configured.

When through FETs connected to one radio frequency terminal to which the shunt FETs are connected are turned off, the shunt FETs increases isolation between the radio frequency terminal and the common terminal. That is, even when the through FETs are turned off, a radio frequency signal may leak to the radio frequency terminal connected to these through FETs in the OFF state, and however, at this time, the leaked radio frequency signal can be escaped to the ground through the shunt FETs in the ON state.

For example, for conduction of electricity between the radio frequency terminal RF1 and the common terminal ANT, the n-staged serially connected through FETs T11 to Tin between the radio frequency terminal RF1 and the common terminal ANT are turned on and the m-staged serially connected shunt FETs S11 to S1m between the radio frequency terminal RF1 and the ground are turned off. At the same time, all of the through FETs between the other radio frequency terminals RF2 to RF6 and the common terminal ANT are turned off and all of the shunt FETs between the other radio frequency terminals RF2 to RF6 and the ground are turned on.

In the above-mentioned case, an ON potential Von is supplied to the control terminal Con1a, the ON potential Von is supplied to the control terminals Con2b to Con6b, an OFF potential Voff is supplied to the control terminal Conib and the OFF potential Voff is supplied to the control terminals Con2a to Con6a.

Here, the ON potential Von is a potential by which each FET is put into a conducted state and its ON resistance is sufficiently small, and is set to 3 V, for example. The OFF potential Voff is a potential by which each FET is put into a blocked state and the blocked state is sufficiently maintained even if an RF signal is superimposed. The OFF potential Voff is determined based on the threshold voltage Vth and the number of connection stages n, m of each FET. For example, given that threshold voltage Vth is 0.3 V and the number of connection stages n, m is 12, transmission output (about 35 dBm) of GSM (Global System for Mobile communications) can be addressed by setting the OFF potential Voff to about −1.5 V.

FIG. 3 is a characteristic diagram showing ON potential dependency of the insertion loss.

FIG. 3 shows dependency of the insertion loss between the terminals on the ON potential Von of the through FETs in the switch circuit 2. As apparent from the figure, as the ON potential Von is smaller, the insertion loss becomes larger. On the contrary, when the ON potential Von exceeds 3 V, the insertion loss is substantially saturated. When the ON potential Von is set to 3.5 V or higher, for example, the FETs constituting the switch circuit 2 may have a problem in terms of reliability. Therefore, in consideration of these matters, a value of the ON potential Von is set.

The control signal for controlling a gate potential of each FET in the switch circuit 2 is generated in the control circuit 3 shown in FIG. 1.

FIG. 4 is a circuit diagram illustrating the configuration of a control circuit of the semiconductor switch shown in FIG. 1.

As shown in FIG. 4, the control circuit 3 decodes the terminal switch signal inputted to the switch signal terminals IN1 to IN3 and outputs the high-level or low-level control signal to the switch circuit 2.

A decoder circuit 5a decodes the 3-bit terminal switch signal inputted to the switch signal terminals IN1 to IN3. The decoded signal is inputted to the driver 6 through an inverting and non-inverting signal generator 5b.

The decoder circuit 5a in FIG. 4 is an example in the case where the 3-bit terminal switch signal is decoded to 6-bit signal, and other configuration can be designed according to a truth table. Further, when a decoded signal is inputted as the terminal switch signal or the number of terminals in the switch circuit 2 is two, the decoder circuit 5a is unnecessary.

In the driver 6, six level shifters 12a to 12f are placed side by side. The first potential Vp is supplied from the high-potential power line 10 and a potential Vn is supplied from a low-potential power line 11. For example, the low-potential power line 11 may be connected to the ground so as to supply a ground potential 0 V to the potential Vn. Alternatively, a negative potential Vn may be supplied from the low-potential power line 11.

Because the level shifters 12a to 12f are configured of differential circuits, the inverting and non-inverting signal generator 5b is provided between the decoder 5a and the driver 6. A power potential Vdd or an internal power potential Vdd1 obtained by stabilizing the power potential Vdd is supplied to other circuit such as the decoder 5a in a previous stage of the driver 6.

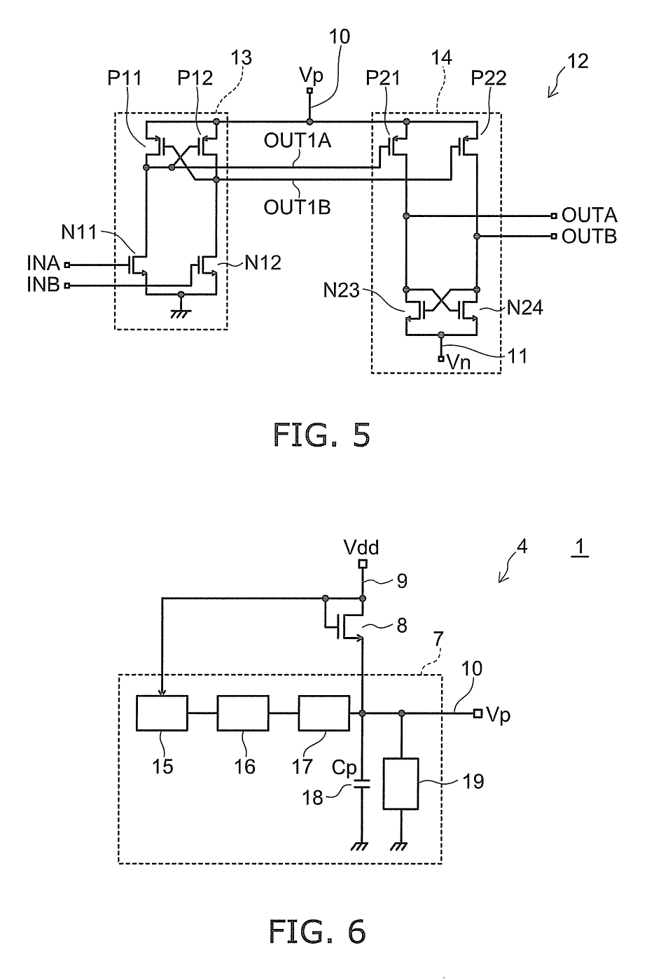

FIG. 5 is a circuit diagram illustrating the configuration of the level shifter of the driver.

FIG. 5 shows the circuit diagram of one level shifter 12 in the driver 6.

As described above, the driver 6 is composed of six level shifters 12a to 12f having the same configuration as the level shifter 12.

The level shifter 12 has a former-stage level shifter 13 and a later-stage level shifter 14. The former-stage level shifter 13 has a pair of N-channel MOSFETs (hereinafter referred to as NMOS) N11, N12 and a pair of P-channel MOSFETs (hereinafter referred to as PMOS) P11, P12. The later-stage level shifter 14 has a pair of PMOSes P21, P22 and a pair of NMOSes N23, N24.

Sources of the NMOSes N11, N12 are connected to the ground. Gates of the NMOSes N11, N12 are connected to a decoder circuit not shown in the previous stage via input terminals INA, INB, respectively.

Drains of the NMOSes N11, N12 are connected to drains of the PMOSes P11, P12, respectively. The first potential Vp is supplied from the power supply circuit 4 to a source of each of the PMOSes P11, P12 through the high-potential power line 10. A gate of the PMOS P11 is connected to a drain of the PMOS P12 and they are connected to one output line OUT1B of a differential output of the former-stage level shifter 13. A gate of the PMOS P12 is connected to a drain of the PMOS P11 and they are connected to the other output line OUT1A of the differential output of the former-stage level shifter 13.

The output lines OUT1A, OUT1B are connected to gates of the PMOSes P21, P22 of the later-stage level shifter 14, respectively. An output signal of the former-stage level shifter 13 is inputted to the later-stage level shifter 14 through the output lines OUT1A, OUT1B. The first potential Vp is supplied from the power supply circuit 4 to sources of the PMOSes P21, P22 through the high-potential power line 10.

A drain of the PMOS P21 is connected to a drain of the NMOS N23 and each of the drains is connected to an output terminal OUTA. A drain of the PMOS P22 is connected to a drain of the NMOS N24 and each of the drains is connected to an output terminal OUTB. The above-mentioned ON potential Von and the OFF potential Voff are supplied to gates of the through FETs and the shunt FETs in the switch circuit 2 in FIG. 2 through the output terminals OUTA, OUTB.

Input level of the differential signal inputted from the decoder circuit not shown in the previous stage to the input terminals INA, INB of the former-stage level shifter 13 are, for example, 1.8 V and 0 V, respectively. The first potential Vp of 3.5 V, for example, is supplied to the high-potential power line 10.

For example, when high level (1.8 V) is inputted to the input terminal INA and low level (0 V) is inputted to the input terminal INB, the potential of the output line OUT1A becomes low level (0 V) and the potential of the output line OUT1B becomes 3.5 V that is equal to the first potential Vp. That is, an output amplitude in the former-stage level shifter 13 is 0 to Vp, that is, about 3.5 V.

An output signal of the former-stage level shifter 13 is inputted to the later-stage level shifter 14. As in the former-stage level shifter 13, the first potential Vp is supplied through the high-potential power line 10. Further, the potential Vn is supplied through the low-potential power line 11.

The first potential Vp is 3.5 V, for example. The potential Vn is 0 V or a negative potential. In the following description, the case where the potential Vn is −1.5 V is used as an example.

Given that the output line OUT1A is at the low level (0 V) and the output line OUT1B is at the high level (3.5 V), the potential of the output terminal OUTA becomes 3.5 V that is equal to the first potential Vp, and the potential of the output terminal OUTB becomes −1.5 V that is equal to the potential Vn. Therefore, the ON potential Von of 3.5 V and the OFF potential Voff of −1.5 V can be supplied to the gates of the through FETs and the shunt FETs in the switch circuit 2 shown in FIG. 2, thereby driving the switch circuit 2.

The former-stage level shifter 13 converts the high level potential to the first potential Vp. The later-stage level shifter 14 converts the low level potential to the potential Vn. Accordingly, the level shifter 12 converts an input signal in which its high level is the power potential Vdd or the internal power potential Vdd1 and its low level is 0 V into an output signal in which its high level is the first potential Vp and its low level is the potential Vn.

When the potential Vn is 0 V, the later-stage level shifter 14 need not be provided.

The level shifter can have various circuit structures other than that shown in FIG. 5. The level shifter in the semiconductor switch 1 can have any circuit structure as long as it has a function to level-shifting the high level to the first potential Vp that is higher than the positive power potential Vdd supplied from the outside.

FIG. 6 is a circuit diagram illustrating a power supply circuit of the semiconductor switch shown in FIG. 1.

As shown in FIG. 6, in the power supply circuit 4, the internal potential generator 7 receives an input of the power potential Vdd from the power supply (power line) 9, generates the first potential Vp that is higher than the input potential Vdd and outputs the first potential Vp to the high-potential power line 10.

The internal potential generator 7 includes an oscillating circuit 15, a charge pump 16, a low-pass filter 17, a capacitative element 18 and a regulator 19. A complementary clock signal generated in the oscillating circuit 15 is supplied to the charge pump 16. The charge pump 16 performs a step-up operation and generates the first potential Vp that is higher than the input potential Vdd. A ripple element contained in the output of the charge pump 16 is removed in the low-pass filter 17 and is outputted as the first potential Vp to the high-potential power line 10. Voltage drop in the low-pass filter 17 is ignored.

The capacitative element 18 and the regulator 19 are connected in parallel between the high-potential power line 10 and the ground. The capacitative element 18 lowers an output impedance of the high-potential power line 10. The regulator 19 stabilizes a value of the first potential Vp to a certain value or smaller.

In the configuration shown in FIG. 6, the capacitative element 18 is provided separately from the low-pass filter 17. However, the capacitative element 18 may be included in the low-pass filter 17.

FIG. 6 shows configuration of the internal potential generator 7 for generating the first potential Vp that is higher than the input potential Vdd. With the same configuration, the internal potential generator 7 may generate a negative potential as the potential Vn and supplies the negative potential to the low-potential power line 11 of the driver 6.

The first transistor 8 is connected between an input and an output of the internal potential generator 7, that is, between the power supply 9 and the high-potential power line 10. A gate and a drain of the first transistor 8 are connected to the power supply 9. A source of the first transistor 8 is connected to the high-potential power line 10 as the output of the internal potential generator. The first transistor 8 is diode-connected.

The input potential Vdd and the first potential Vp are inputted to the first transistor 8. Here, the first transistor 8 is an NMOS and its threshold voltage Vth is set so that the first transistor 8 is turned on when the first potential Vp becomes smaller than the input potential Vdd. Thus, when the first potential Vp becomes smaller than the input potential Vdd, the high-potential power line 10 is electrically connected to the power supply 9. Therefore, the first potential Vp is kept to be equal to or larger than the input potential Vdd.

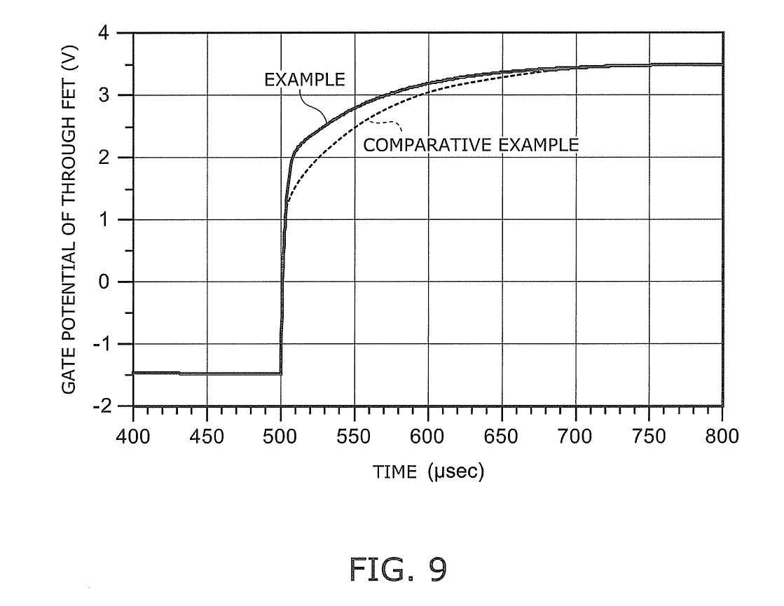

Thereby, as described with reference to FIG. 8 and FIG. 9, the semiconductor switch 1 can prevent instantaneous drop of the first potential Vp on switching and prevent increase in the insertion loss immediately after switching.

Further, for example, by using an SOI (Silicon On Insulator) CMOS (Complementary Metal Oxide Semiconductor) process, the switch circuit 2, the control circuit 3 and the power supply circuit 4 can be formed on a same semiconductor substrate. This can achieve reduction of costs and size.

By using the MOSFET formed on the SOI substrate in this manner, a radio frequency switch having similar radio frequency capabilities to those of a compound semiconductor HEMT (High Electron Mobility Transistor) can be realized.

By the way, operations and effects of the first transistor 8 become more apparent as compared to the case where no first transistor 8 is provided.

Use of the CMOS process causes below-mentioned problems.

When attempting to achieve the same capabilities as those of HEMT in MOSFET, it is needed to increase the number of stages of the FETs in the switch circuit 2 and the gate width. Because the radio frequency MOSFET requires a microscopic process, in terms of element withstanding voltage, a difference between the ON voltage and the OFF voltage needs to be smaller as compared to HEMT.

For this reason, the number of connection stages of FETs must be increased. As the number of stages increases, the insertion loss increases and accordingly, the gate width needs to be increased.

This means that a load capacity of each of the level shifters 12a to 12f in the driver 6 increases. For example, a sum of gate capacitance of the through FETs to one RF port in the switch circuit 2 is as large as 100 pF. The level shifters 12a to 12f have to charge and discharge such large capacity.

As in the semiconductor switch 1, in the case where power supplied to the level shifters 12a to 12f is internally generated, unless an output impedance of the internal potential generator 7 is extremely low, the first potential Vp and the potential Vn greatly vary in the switching operation.

Here, variation in the first potential Vp on switching is noted. It is assumed that one level shifter supplies low level to the through FETs, and then, the low level is changed to high level on switching. In this case, a large transient current flows from the high-potential power line 10 of the level shifter to the output terminal. This current is to be supplied from the capacitative element 18 in FIG. 5. However, assuming that a capacitance Cp of the capacitative element 18 is about 100 pF, a sufficient transient current cannot be supplied.

Therefore, without the first transistor 8, the first potential Vp instantaneously drops on switching. After that, the first potential Vp gradually get closer to a desired value due to current supply from the charge pump 16. However, since the current supply capability of the built-in charge pump 16 is low, its time constant becomes large.

The radio frequency switch has a requirement for switch time. For example, in GSM, the radio frequency signal may be inputted after a lapse of 18 μs after switching. Thus, sufficient radio frequency characteristics such as insertion loss must be obtained at 18 μs from switching.

If the capacitance Cp of the capacitative element 18 can be increased, instantaneous drop of the first potential Vp on switching can be prevented. However, to prevent the instantaneous drop, the capacitance Cp needs to be increased to about 1000 pF, for example. A large chip area is required to have such large capacity. In this case, size reduction as one of merits in using the CMOS process is largely obstructed.

As described above, the semiconductor switch using the SOI CMOS process has the problem that, without the first transistor 8, the insertion loss immediately after switching becomes large.

On the contrary, in the semiconductor switch 1 according to First embodiment, the first transistor 8 is connected between the input and the output of the power supply circuit 4.

The threshold voltage Vth of the first transistor 8 is set to a smallest possible value under the condition that Vth is equal to or larger than its variation ΔVth. In other words, the threshold voltage Vth is set to a value that is as close to 0 as possible so that Vth does not become negative even if Vth varies within a range of ΔVth. For example, given that the variation ΔVth of the threshold voltage Vth is ±0.1 V, Vth is set to be equal to or larger than 0.1 V.

Assuming that the threshold voltage Vth is set to 0.1 V, the gate and the drain are connected and the diode-connected first transistor 8 is put into the conducted state with a drain-source voltage Vds≧0.1 V.

A back gate of the first transistor 8 is a floating gate.

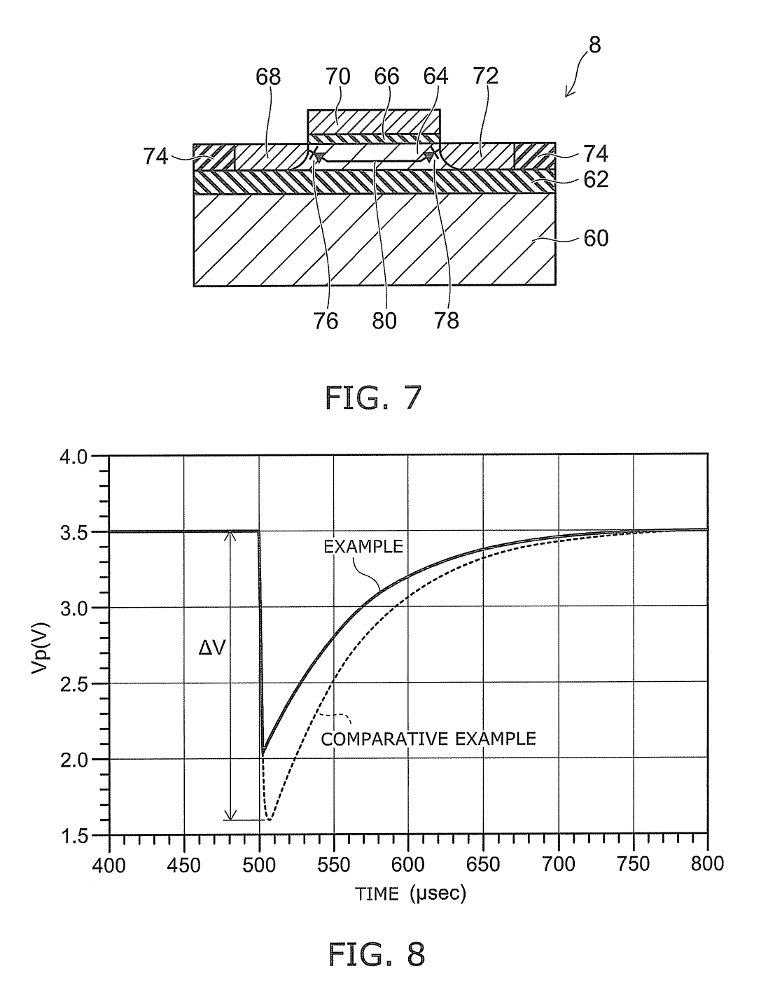

FIG. 7 is a sectional view of the first transistor.

As shown in FIG. 7, the first transistor 8 is an NMOS formed on the SOI substrate.

An embedded oxide film layer 62 is provided in a silicon (Si) substrate 60. A source region (source) 68 and a drain region (drain) 72 are provided on the embedded oxide film layer 62 across an SOI layer 64. Further, an element separating layer 74 is provided on the embedded oxide film layer 62 so as to surround the source region 68, the SOI layer 64 and the drain region 72. A gate electrode (gate) 70 is provided above the source region 68, the SOI layer 64 and the drain region 72 via a gate oxide film 66.

The lower side of the channel of the first transistor 8 is insulated from the silicon (Si) substrate 60 as a supporting substrate by the embedded oxide film layer 62. The lateral sides of the channel is insulated from other elements by the element separating layer 74. A back gate 80 is electrically floating.

The back gate is p-type and the source region 68 and the drain region 72 are N-type. Accordingly, a parasitic diode 76 is formed between the channel and the source region 68 and a parasitic diode 78 is formed between the channel and the drain region 72.

In the diode-connected first transistor 8, in the case of a positive bias, when the drain-source voltage Vds is equal to or larger than the threshold voltage Vth (Vds≧Vth), a forward current flows. However, in the case of a reverse bias, due to existence of the anti-series connected parasitic diodes 76, 78, no reverse current flows.

Next, operations of the semiconductor switch 1 will be described.

Here, it is assumed that the first potential Vp generated in the internal potential generator 7 is 3.5 V and the positive power potential Vdd supplied from the outside is 2.5 V. In a steady state, since the first transistor 8 is biased in the reverse direction, no current flows from the power supply 9 to the high-potential power line 10 via the first transistor 8.

It should be noted that, as distinct from the general NMOS, the back gate 80 in the first transistor 8 is not connected to the source region 68. When the back gate 80 is connected to the source region 68, the parasitic diode 78 between the back gate and the drain is put into the ON state at bias in the reverse direction. For this reason, a current flows to the parasitic diode 78, resulting in that a value of the first potential Vp is decreased from an original value.

Next, operations on switching will be described.

As described above, on switching, electrical charges charged in the capacitative element 18 flow into the gate capacitance of the FETs in the switch circuit 2, which are switched from the OFF state to the ON state, through the level shifters 12a to 12f. As a result, the first potential Vp decreases instantaneously. However, when the first potential Vp becomes smaller than Vdd-Vth, the first transistor 8 is put into the conducted state. For this reason, the capacitative element 18 is charged with a current from the power potential Vdd of the power supply 9 through the first transistor 8 until the first potential Vp reaches Vdd-Vth.

When the first potential Vp exceeds Vdd-Vth, current supply from the first transistor 8 stops. The capacitative element 18 is charged with a current supplied from the charge pump 16.

Through the above-mentioned operations, the instantaneous drop of the first potential Vp on switching is prevented as distinct from the case without the first transistor 8.

FIG. 8 is a waveform diagram of the first potential on terminal switching.

FIG. 8 shows simulated waveforms of the first potential Vp on switching in an example and in a comparative example without the first transistor 8.

Simulation is performed under conditions that a steady value of the first potential Vp is 3.5 V, the power potential Vdd is 2.5 V, the threshold voltage Vth of the first transistor 8 is 0.3 V and the switch is performed at a time of 500 μs.

At the instant when the switch is performed, the first potential Vp rapidly lowers both in the example and in the comparative example. However, the first potential Vp drops to about 1.6 V in the comparative example, while the first potential Vp drops only to about 2.1 V in the example.

FIG. 9 is a waveform diagram of the control signal on terminal switching.

FIG. 9 shows simulated waveforms of the gate potential of the through FETs in the switch circuit 2, which are switched on. In FIG. 9, a negative potential of −1.5 V is supplied as the potential Vn supplied to the level shifters 12a to 12f.

The gate potential at 18 μs after switching is 1.7 V in the comparative example, while it is improved to 2.3 V in the example. As compared to the ON voltage dependency of the insertion loss in FIG. 3, the insertion loss at 18 μs after switching is improved by about 0.1 dB from that in the comparative example.

The first transistor 8 can be manufactured under the same ion injection conditions as those for each FET in the switch circuit 2, and the manufacturing process does not become complicated in achieving this example.

As described above, the semiconductor switch 1 can prevent instantaneous drop of the first potential Vp on switching, thereby preventing increase in the insertion loss immediately after switching.

Next, effectiveness of the first transistor 8 is considered.

Noting the group of through FETs having the largest total gate capacitance among the groups of n-staged serially connected through FETs in the switch circuit 2, the time when the group of the through FETs are switched from the OFF state to the ON state is considered.

Here, the existence of the shunt FETs that are smaller than the through FETs is ignored.

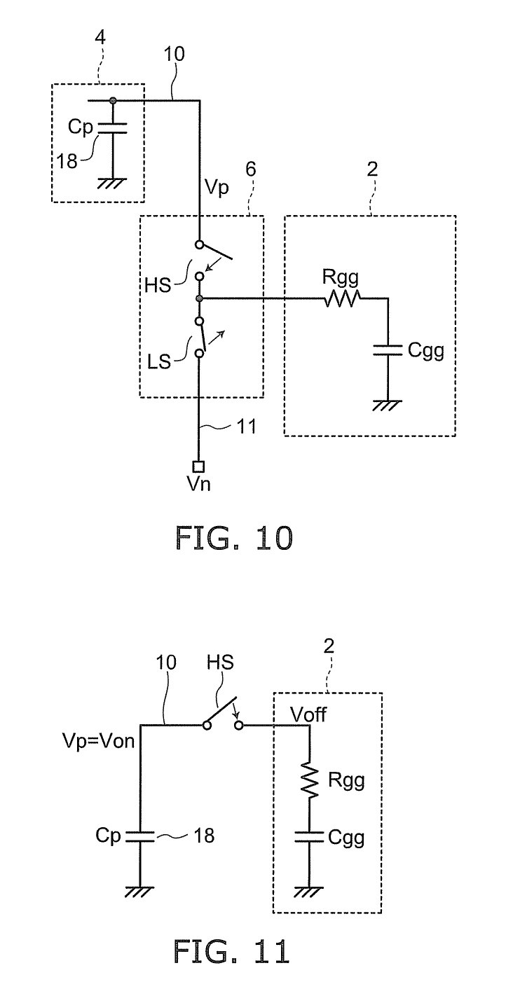

FIG. 10 is a circuit diagram showing an equivalent circuit of the semiconductor switch on switching of connection in the switch circuit 2.

In FIG. 10, the switch circuit 2 in the semiconductor switch 1 is represented by a resistor having a resistance value Rgg and an electrostatic capacitance Cgg. The level shifter in the driver 6 in the control circuit 3 is represented by a high-side switch HS and a low-side switch LS. The power supply circuit 4 is represented by the capacitative element 18 having an electrostatic capacitance Cp.

Herein, the resistance value Rgg is a combined value obtained when resistors provided in gates of the noted group of through FETs are connected in parallel. The electrostatic capacitance Cgg is a total gate capacitance of the noted group of through FETs.

FIG. 11 is a circuit diagram showing an equivalent circuit for computing variation of the first potential.

FIG. 11 shows the equivalent circuit in the semiconductor switch 1 at the time when the group of through FETs are switched from the OFF state to the ON state.

It is the equivalent circuit for computing variation LW in the first potential Vp in the comparative example shown in FIG. 8.

In an initial state, the high-side switch HS is turned off. The capacitative element 18 is charged with the ON potential Von and the electrostatic capacitance Cgg of the switch circuit 2 is charged with the OFF potential Voff. Here, the ON potential Von is equal to the first potential Vp in the steady state and the OFF potential Voff is equal to the potential Vn in the steady state.

When computing the potential of the switch circuit 2 after the high-side switch HS is turned on, an expression (1) is obtained.

ΔV=Cgg×(Von−Voff)/(Cp+Cgg) (1)

For example, in the case of Cgg=70 pF, Cp=200 pF, Von=3.5 V and Voff=−1.5 V, then ΔV≈1.30 V.

The reason why the resistance value Rgg does not exist in the expression (1) is that, after an instantaneous current flows from the capacitative element 18 to the switch circuit 2, a potential difference between both ends of the resistance value Rgg is not caused.

The condition that the first transistor 8 becomes effective is that an expression (2) is satisfied without the first transistor 8.

ΔV>Von−Vdd (2)

Where, Vdd is power potential.

An expression (3) is acquired from the expressions (1), (2).

Cgg×(Von−Voff)/(Cp+Cgg)>Von−Vdd (3)

The threshold voltage Vth of the first transistor 8 needs to be further considered so that the first transistor 8 is turned and becomes effective. For example, when using the same numeral values as described above, in the case of Vdd=2.5 V, Vth becomes smaller than 0.3 V according to the expression (3).

Therefore, in the semiconductor switch 1, it is desired that the threshold voltage Vth of the first transistor 8 is as small as possible in consideration of variation so as not to be negative.

It can be considered to use a diode in place of the first transistor 8. However, when using the same numeral values as described above, it is impossible to use a pn-junction diode in place of the first transistor 8. For example, in the case of a silicon pn-junction diode, since the diode is turned on when a forward voltage is about 0.6 to 0.7 V, the diode is not turned on in the above-mentioned numeral values.

Although it can be considered to use a diode turning on with a low voltage, such as a Schottky barrier diode, it is difficult to integrate the diode into the switch circuit 2 on the same semiconductor substrate in the SOI CMOS process.

As shown in FIG. 7, in the semiconductor switch 1, an NMOS formed on the SOI substrate is used as the first transistor 8. However, a PMOS can be employed.

However, since the NMOS is superior to the PMOS in high-speed performance, when the first potential Vp decreases to the potential Vdd−Vth or smaller, instantaneous electrical conduction can be achieved. Moreover, in the case of the same ON resistance, the NMOS can have a smaller channel width and layout area than the PMOS.

### Second Embodiment

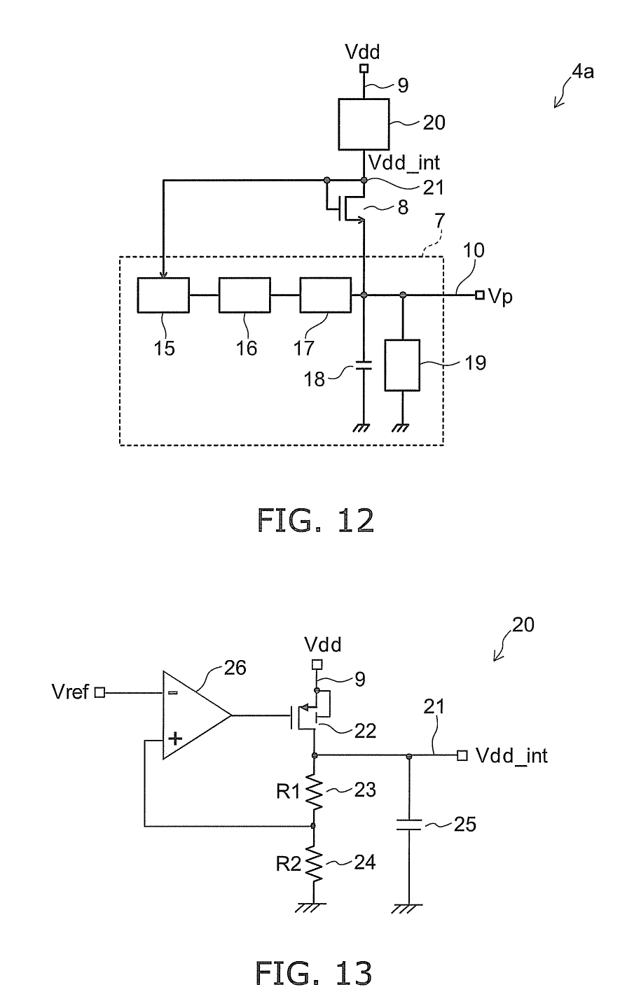

FIG. 12 is a circuit diagram illustrating the configuration of a power supply circuit of a semiconductor switch according to a second embodiment.

As shown in FIG. 12, in a power supply circuit 4a, a step-down circuit 20 is added to the power supply circuit 4 shown in FIG. 6. The same components in FIG. 12 as those in the power supply circuit 4 in FIG. 6 are given the same reference numerals.

The step-down circuit 20 receives an input of the power potential Vdd supplied to the power supply 9 and supplies a power potential Vdd_int to an internal circuit. Even when the power potential Vdd supplied from the outside varies, a constant power potential Vdd_int can be supplied to the internal circuit. Moreover, the power potential Vdd is decreased so that the power potential Vdd_int of the internal circuit does not exceed a maximum rating of the internal circuit. The power potential Vdd_int is supplied to the internal potential generator 7, and input potential of the internal potential generator 7 becomes Vdd_int.

The first transistor 8 is connected between the input and the output of the internal potential generator 7, that is, between an internal power line 21 as an output of the step-down circuit 20 and the high-potential power line 10. The gate and the drain of the first transistor 8 are connected to the internal power line 21. The source of the first transistor 8 is connected to the high-potential power line 10 as the output of the internal potential generator. The first transistor 8 is diode-connected.

The input potential Vdd_int and the first potential Vp are inputted to the first transistor 8. As described above, the first transistor 8 is the NMOS and the threshold voltage Vth is set so that the first transistor 8 is turned on when the first potential Vp becomes lower than the input potential Vdd_int. Thus, when the first potential Vp becomes lower than the input potential Vdd_int, the high-potential power line 10 is electrically connected to the internal power line 21. Accordingly, the first potential Vp is kept to be equal to or higher than the input potential Vdd_int.

FIG. 13 is a circuit diagram illustrating the configuration of the step-down circuit of the power supply circuit shown in FIG. 12.

As shown in FIG. 13, in the step-down circuit 20, the power potential Vdd_int obtained by lowering the power potential Vdd inputted from the power supply 9 is outputted to the internal power line 21.

An output transistor 22 is connected between the power supply 9 and the internal power line 21. The output transistor 22 is formed of a PMOS. Feedback resistors 23, 24 are serially connected between the internal power line 21 and the ground. A capacitance 25 is also connected between the internal power line 21 and the ground.

The power potential Vdd_int is divided by the feedback resistors 23, 24 and fed back to a non-inverting terminal of an error amplifying circuit 26. A reference Vref is inputted to an inverting terminal of the error amplifying circuit 26. The error amplifying circuit 26 amplifies an error of the power potential Vdd_int to control the output transistor 22.

The power potential Vdd_int of the internal power line 21 is expressed as an expression (4).

Vdd_{—}int=(1+R1/R2)×Vref (4)

Here, R1, R2 are resistance values of the feedback resistors 23, 24, respectively.

FIG. 13 shows configuration of a constant voltage circuit as the step-down circuit 20. However, it is only needed to lower the power potential Vdd to a potential that is equal to or smaller than the maximum rating of the internal circuit and supply the power potential Vdd_int thus obtained. The circuit is not necessarily the constant voltage circuit.

The gate width of the output transistor 22 is set to a sufficiently large value so that the step-down circuit 20 can sufficiently supply the current when a forward current flows in the first transistor 8.

Therefore, even when the power supply circuit 4a is used in place of the power supply circuit 4 in the semiconductor switch 1 in FIG. 1, instantaneous drop of the first potential Vp on switching can be prevented, thereby preventing increase in the insertion loss immediately after switching.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor switch comprising:
a power supply circuit including,
an internal potential generator connected to a power supply, the internal potential generator generating a first potential higher than an input potential, and
a first transistor connected between an input and an output of the internal potential generator, the first transistor being turned on when the first potential becomes lower than the input potential and having a threshold voltage being set so as to keep the first potential not lower than the input potential;
a control circuit configured to receive the first potential to output a high-level or low-level control signal; and
a switch circuit configured to receive an input of the control signal to switch connection between terminals.

2. The switch according to claim 1, wherein
in the first transistor, a gate and a drain are connected to the input of the internal potential generator, a source is connected to the output of the internal potential generator and a back gate is a floating N-channel MOSFET.

3. The switch according to claim 1, wherein
the first transistor and the switch circuit are provided on one SOI substrate.

4. The switch according to claim 1, wherein
the switch circuit includes
a through FET connected between an common terminal and a radio frequency terminal, and
a shunt FET connected between the radio frequency terminal and the ground, and
the first transistor has the threshold voltage being same as a threshold voltage of the through FET or the shunt FET.

5. The switch according to claim 1, wherein the threshold voltage of the first transistor is 0.1 V.

6. The switch according to claim 1, wherein a current supply capability of the internal potential generator is smaller than a transit current flowing to the control circuit when the switch circuit switches connection between the terminals.

7. The switch according to claim 1, wherein the internal potential generator further includes a capacitative element connected between the output and the ground.

8. The switch according to claim 7, wherein a current supply capability of the internal potential generator is smaller than a transit current flowing to the control circuit when the switch circuit switches connection between the terminals.

9. The switch according to claim 1, wherein
the internal potential generator includes
an oscillating circuit,
a charge pump circuit operated by an output of the oscillating circuit, and
a low-pass filter configured to smooth an output of the charge pump circuit.

10. The switch according to claim 9, wherein a current supply capability of the internal potential generator is smaller than a transit current flowing to the control circuit when the switch circuit switches connection between the terminals.

11. The switch according to claim 1, wherein
the power supply circuit further includes
a step-down circuit being connected between the power supply and the internal potential generator, the step-down circuit configured to lower the potential of the power supply to output the lowered potential to the internal potential generator and the first transistor.

12. The switch according to claim 11, wherein
in the first transistor, a gate and a drain are connected to the input of the internal potential generator, a source is connected to the output of the internal potential generator and a back gate is a floating N-channel MOSFET.

13. The switch according to claim 11, wherein
the first transistor and the switch circuit are provided on one SOT substrate.

14. The switch according to claim 11, wherein
the switch circuit includes
a through FET connected between an common terminal and a radio frequency terminal, and
a shunt FET connected between the radio frequency terminal and the ground, and
the first transistor has the threshold voltage being same as a threshold voltage of the through FET or the shunt FET.

15. The switch according to claim 11, wherein the threshold voltage of the first transistor is 0.1 V.

16. The switch according to claim 11, wherein a current supply capability of the internal potential generator is smaller than a transit current flowing to the control circuit when the switch circuit switches connection between the terminals.

17. The switch according to claim 11, wherein the internal potential generator further includes a capacitative element connected between the output and the ground.

18. The switch according to claim 17, wherein a current supply capability of the internal potential generator is smaller than a transit current flowing to the control circuit when the switch circuit switches connection between the terminals.

19. The switch according to claim 11, wherein
the internal potential generator includes
an oscillating circuit,
a charge pump circuit operated by an output of the oscillating circuit, and
a low-pass filter configured to smooth an output of the charge pump circuit.

20. The switch according to claim 19, wherein a current supply capability of the internal potential generator is smaller than a transit current flowing to the control circuit when the switch circuit switches connection between the terminals.
